(19) United States
(12) Patent Application Publication
(10) Pub. No.: US 2026/0143971 A1
(43) Pub. Date: May 21, 2026

(54) TIERED BOTTOM ELECTRODES

(71) Applicant: INTERNATIONAL BUSINESS MACHINES CORPORATION, Armonk, NY (US)

(72) Inventors: Oscar van der Straten, Guilderland Center, NY (US); Linda W Wangoh, Cohoes, NY (US); Chih-Chao Yang, Glenmont, NY (US)

(21) Appl. No.: 18/952,323

(22) Filed: Nov. 19, 2024

(51) Int. Cl. H10N 50/01; H10N 50/80

(52) U.S. Cl. CPC H10N 50/01; H10N 50/80

(57) ABSTRACT

Magnetic tunnel junction devices and methods of forming the same include a first bottom electrode that includes sloped sidewalls. An MTJ stack is on the bottom electrode and has a bottom surface that is larger than a top surface of the bottom electrode. A top electrode is on the MTJ stack.

### BACKGROUND

The present invention generally relates to magnetic tunnel junctions and, more particularly, to tiered bottom electrodes for magnetic tunnel junctions.

Magnetic tunnel junction (MTJ) devices make use of quantum tunneling effects to store information in the orientation of the magnetic field of a free magnetic layer relative to a reference magnetic layer. A tunnel barrier separates the free magnetic layer from the reference magnetic layer to prevent conventional current from traveling from one layer to the other during switching and reading, so that current flow is limited to electron movement by quantum tunneling.

When magnetizations of the free magnetic layer and the reference magnetic layer are parallel with one another, electrons have an easier time tunneling through the tunnel barrier when a read voltage is applied, producing a first current that corresponds to a first stored state. When the magnetizations are antiparallel to one another, fewer electrons will tunnel through the tunnel barrier, producing a second (lower) current that corresponds to a second stored state. The orientation of the magnetization of the free layer, relative to the reference layer, can be changed by applying an external magnetic field, thereby storing information on the MTJ device.

### SUMMARY

A magnetic tunnel junction (MTJ) device includes a first bottom electrode that includes sloped sidewalls. An MTJ stack is on the bottom electrode and has a bottom surface that is larger than a top surface of the bottom electrode. A top electrode is on the MTJ stack.

An MTJ device includes a first tiered bottom electrode with sloped sidewalls that includes a second conductor platform on a first conductor platform, with a first mask layer between the first conductor platform and the second conductor platform. An MTJ stack is on the bottom electrode, having a bottom surface that is larger than a top surface of the bottom electrode and that is smaller than a bottom surface of the first tiered bottom electrode. A top electrode is on the MTJ stack.

A method of forming an MTJ device includes forming a first bottom electrode with sloped sidewalls. A dielectric layer that covers the sloped sidewalls of the first bottom electrode is formed. A set of MTJ layers is formed on the first bottom electrode. The set of MTJ layers are anisotropically etched to form an MTJ stack, with the first bottom electrode being protected from the etching by the dielectric layer.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view of a step in the fabrication of a magnetic tunnel junction (MTJ) device, showing the formation of a conductive interconnect within a dielectric layer, in accordance with an embodiment of the present invention;

FIG. 2 is a cross-sectional view of a step in the fabrication of an MTJ device, showing the formation of a conductive cap on the conductive interconnect, in accordance with an embodiment of the present invention;

FIG. 3 is a cross-sectional view of a step in the fabrication of an MTJ device, showing deposition of a first conductor layer on the conductive cap, in accordance with an embodiment of the present invention;

FIG. 4 is a cross-sectional view of a step in the fabrication of an MTJ device, showing the formation of a first conductor platform with sloped sidewalls by etching the first conductor layer with an angled etch, in accordance with an embodiment of the present invention;

FIG. 5 is a cross-sectional view of a step in the fabrication of an MTJ device, showing the formation of a second conductor layer over the first conductor platform, in accordance with an embodiment of the present invention;

FIG. 6 is a cross-sectional view of a step in the fabrication of an MTJ device, showing the formation of a second conductor platform with sloped sidewalls on the first conductor platform by etching the second conductor layer with an angled etch, in accordance with an embodiment of the present invention;

FIG. 7 is a cross-sectional view of a step in the fabrication of an MTJ device, showing the formation of MTJ layers and a top conductor layer, in accordance with an embodiment of the present invention;

FIG. 8 is a cross-sectional view of a step in the fabrication of an MTJ device, showing the an etch of the MTJ layers and the top conductor layers to form an MTJ stack and a top electrode, in accordance with an embodiment of the present invention;

FIG. 9 is a cross-sectional view of a step in the fabrication of an MTJ device, showing the formation of a top conductive interconnect on the top electrode, in accordance with an embodiment of the present invention;

FIG. 10 is a cross-sectional view of an alternative embodiment of an MTJ device, where multiple tiered conductive electrodes are positioned side-by-side under the MTJ stack, in accordance with an embodiment of the present invention;

FIG. 11 is a cross-sectional view of an alternative embodiment of an MTJ device, where a unitary conductive electrode is positioned under the MTJ stack, in accordance with an embodiment of the present invention;

FIG. 12 is a block/flow diagram of a method for forming an MTJ device having a bottom electrode with sloped sidewall surfaces, in accordance with an embodiment of the present invention.

### DETAILED DESCRIPTION

During fabrication of a magnetic tunnel junction (MTJ) device, a stack of layers is formed over a bottom electrode and is then patterned. The stack of layers includes a free magnetic layer, a reference magnetic layer, and a tunnel barrier that electrically insulates the free magnetic layer from the reference magnetic layer. During patterning of this stack, and particularly during an anisotropic etch that exposes an underlying metal electrode, etched material may be sputtered back and may thus be deposited on sidewalls of the MTJ stack. This sputtered material may include metal that short-circuits the free magnetic layer and the reference magnetic layer, thereby providing a conventional path for current to flow around the tunnel barrier. Such a conductive path would have a consistent resistance, regardless of the orientation of the free layer’s magnetization, and so would make it impossible to determine the orientation of that layer—thereby rendering it impossible to read information that is stored in the MTJ device.

To prevent this, the bottom electrode may first be patterned so that the surface area of a top surface of the bottom electrode is not exposed to the etch of the MTJ stack. The bottom electrode may have a tapered profile, with a top surface that has a smaller area than the MTJ stack and a larger bottom surface to provide good conductive contact with underlying structures. Because the metal of the top surface is protected by the body of the MTJ stack when the MTJ stack is etched, no conductive material is exposed to the etch and so none sputters back during. This prevents the short-circuit from forming.

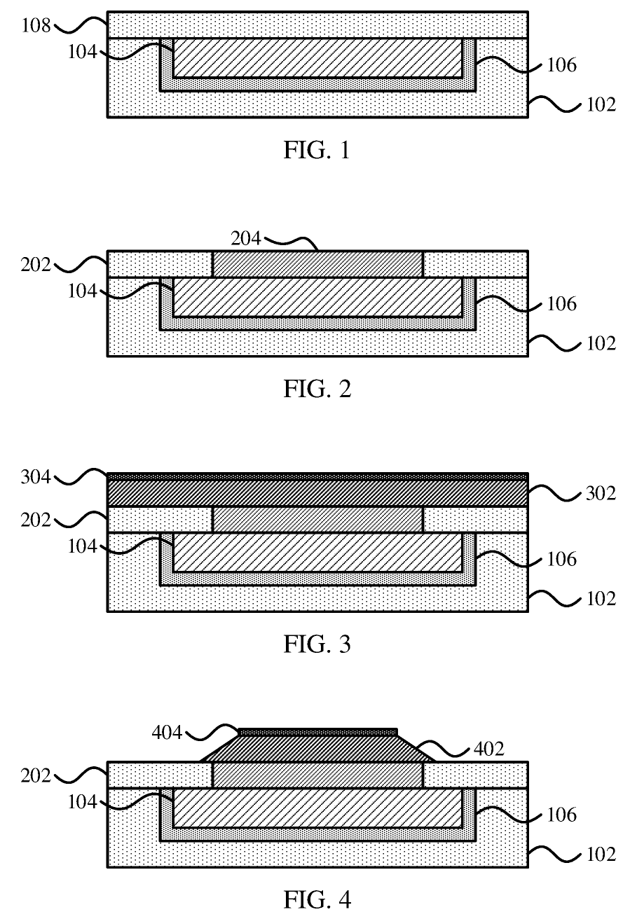

Referring now to FIG. 1, a cross-sectional view of a step in the fabrication of an MTJ device is shown. A bottom conductive interconnect 104 is formed within a trench in a dielectric layer 102. A diffusion barrier layer 106 may be formed between the bottom conductive interconnect 104 and the dielectric layer 102. A dielectric cap 108 is formed over the bottom conductive interconnect 104. The bottom conductive interconnect 104 may provide signal communication to the MTJ device from other devices, for example providing a read voltage that can be used to determine the information stored on the MTJ device.

The dielectric layer 102 may be formed from any appropriate electrically insulating material, such as silicon dioxide or a low-k dielectric material. It is specifically contemplated that the bottom conductive interconnect 104 may be formed from a conductive metal such as copper, cobalt, ruthenium, tungsten, nickel, titanium, molybdenum, tantalum, platinum, silver, gold, iridium, rhenium, rhodium, and alloys thereof, it should be understood that alternative conductive materials may be used instead. The dielectric cap 108 may be formed from any appropriate dielectric material, such as silicon dioxide or silicon nitride.

The trench may be formed in the dielectric layer 102 by any appropriate etching process. For example, the area of the trench may be defined by a photolithographic process and a timed anisotropic etch may be used to remove material from the dielectric layer 102 to a predetermined depth. Specifically, a pattern may be produced by applying a photoresist to the surface to be etched. The photoresist may be exposed to a pattern of radiation and then the pattern may be developed into the photoresist utilizing a resist developer. Once the patterning of the photoresist is completed, the sections covered by the photoresist are protected while the exposed regions are removed using an etching process that removes the unprotected regions.

Reactive ion etching (RIE) may be used for the anisotropic etch. RIE is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation.

Referring now to FIG. 2, a cross-sectional view of a step in the fabrication of an MTJ device is shown. The dielectric cap 108 is patterned and etched to form an opening that exposes the top surface of the bottom conductive interconnect 104. A selective RIE may be used to etch the opening, with the selective etch stopping on the material of the bottom conductive interconnect 104. As used herein, the term “selective” in reference to a material removal process denotes that the rate of material removal for a first material is greater than the rate of removal for at least another material of the structure to which the material removal process is being applied.

A conductive cap 204 may be formed in the opening, making contact with the bottom conductive interconnect 104. The conductive cap 204 may be formed from any appropriately conductive material, such as tantalum nitride. This conductive material may be deposited by any appropriate process, with excess material being removed by a chemical mechanical planarization (CMP) process, leaving conductive cap 204.

Various deposition processes may be used herein for different purposes, such as chemical vapor deposition (CVD), physical vapor deposition (PVD), atomic layer deposition (ALD), or gas cluster ion beam (GCIB) deposition. Some deposition processes, such as ALD, may deposit material conformally, whereas others, such as PVD or GCIB, may provide a more directional deposition. CVD may range from highly conformal to highly non-conformal depending on the formulation.

CVD is a deposition process in which a deposited species is formed as a result of chemical reaction between gaseous reactants at greater than room temperature (e.g., from about 25 °C about 900 °C). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

CMP is performed using, e.g., a chemical or granular slurry and mechanical force to gradually remove upper layers of the device. The slurry may be formulated to be unable to dissolve, for example, the remaining dielectric cap 202, resulting in the CMP process’s inability to proceed any farther than that layer.

Referring now to FIG. 3, a cross-sectional view of a step in the fabrication of an MTJ device is shown. A first conductor layer 302 is deposited over the remaining dielectric cap 202 and the conductive cap 204 using any appropriate deposition process to an exemplary thickness between about 5nm and about 50nm. A first mask layer 304 is deposited over the first conductor layer 302 using any appropriate deposition process. It is specifically contemplated that the first conductor layer 302 and the first mask layer 304 are selectively etchable with respect to one another. In an exemplary embodiment, the first conductor layer 302 is formed from tungsten and the first mask layer 304 is formed from tungsten nitride. In an exemplary embodiment, the first conductor layer 302 is formed from molybdenum and the first mask layer 304 is formed from molybdenum nitride.

Referring now to FIG. 4, a cross-sectional view of a step in the fabrication of an MTJ device is shown. The first mask layer 304 is patterned and selectively etched to form first mask 404. The exposed portions of the first conductor layer 302 are selectively and anisotropically etched to form first conductor platform 402. The etch of the first conductor platform 402 is formulated to create sloped side surfaces around the first mask 404.

In some embodiments, the sloped side surfaces of the first conductor platform 402 may have sidewall angles between about 30 degrees and about 60 degrees, but it should be understood that shallower or steeper sidewall angles are also contemplated. These sloped sidewalls provide metal contact surface area to the conductive cap 204 below, while ensuring a sufficient vertical spacing between the sloped sidewalls and overlying structures to provide electrical insulation. These sloped sidewall surfaces thereby reduce the likelihood of an over-etch reaching the conductive material of the first conductor platform and causing resputtering from below. These sloped sidewall surfaces may be created using an angled ion beam etch.

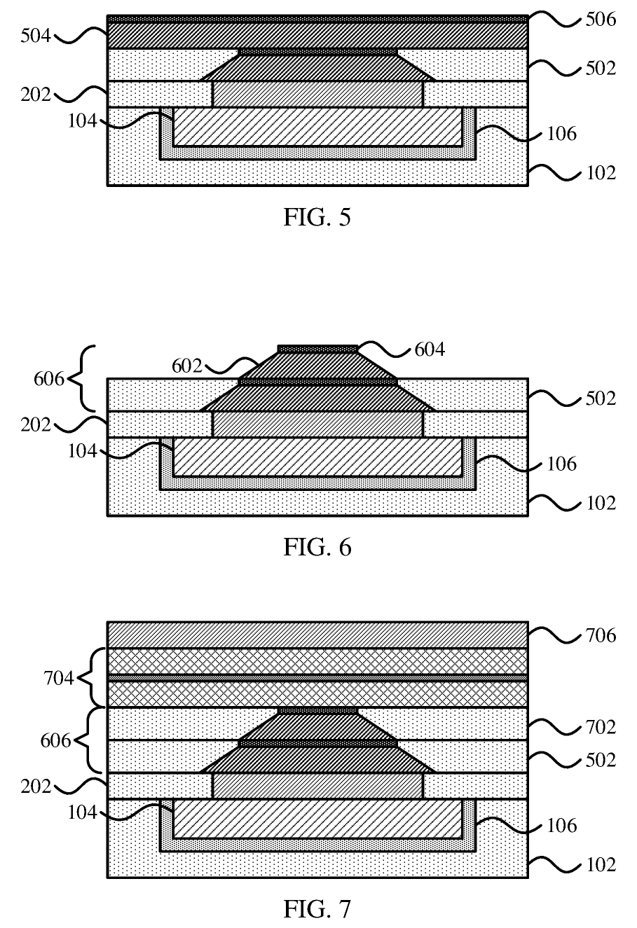

Referring now to FIG. 5, a cross-sectional view of a step in the fabrication of an MTJ device is shown. A layer of dielectric material 502, such as silicon dioxide, is deposited over the first mask 404 and the first conductor platform 402 and is polished back to the level of a top surface of the first mask 404 using a CMP process.

A second conductor layer 504 is deposited over the first mask 404 and the layer of dielectric material 502 using any appropriate deposition process, to an exemplary thickness between about 2nm and about 20nm. A second mask layer 506 is deposited over the second conductor layer 504 using any appropriate deposition process. It is specifically contemplated that the second conductor layer 504 and the second mask layer 506 are selectively etchable with respect to one another. In an exemplary embodiment, the second conductor layer 504 is formed from tungsten and the second mask layer 506 is formed from tungsten nitride. In an exemplary embodiment, the second conductor layer 504 is formed from molybdenum and the second mask layer 506 is formed from molybdenum nitride.

Referring now to FIG. 6, a cross-sectional view of a step in the fabrication of an MTJ device is shown. The second mask layer 506 is patterned and selectively etched to form second mask 604. The exposed portions of the second conductor layer 504 are selectively and anisotropically etched to form second conductor platform 602. The etch of the second conductor platform 602 is formulated to create sloped side surfaces around the second mask 604. Taken together, the first conductor platform 402, the first mask 404, the second conductor platform 602, and the second conductor platform 602 form a tiered bottom electrode 606.

Referring now to FIG. 7, a cross-sectional view of a step in the fabrication of an MTJ device is shown. A layer of dielectric material 702, such as silicon dioxide is deposited over the second mask 604 and the second conductor platform 602 and is polished back to the level of a top surface of the second mask 604 using a CMP process.

A stack of layers 704 is deposited over the second mask 604 and the layer of dielectric material 702 using any appropriate sequence of deposition processes. The stack of layers 704 may include, e.g., a free magnetic layer, a tunnel barrier layer, and a reference magnetic layer. Any appropriate materials may be used to form the stack of layers 704, with the aim of forming an MTJ device. For example, the free magnetic layer and the reference magnetic layer may include a cobalt iron boron alloy while the tunnel barrier layer may include magnesium oxide. The stack of layers 704 may further include, e.g., a cobalt-based synthetic antiferromagnet. A top conductor layer 706 is deposited over the stack of layers 704 using any appropriate deposition process from any appropriate conductive material, such as tantalum or ruthenium.

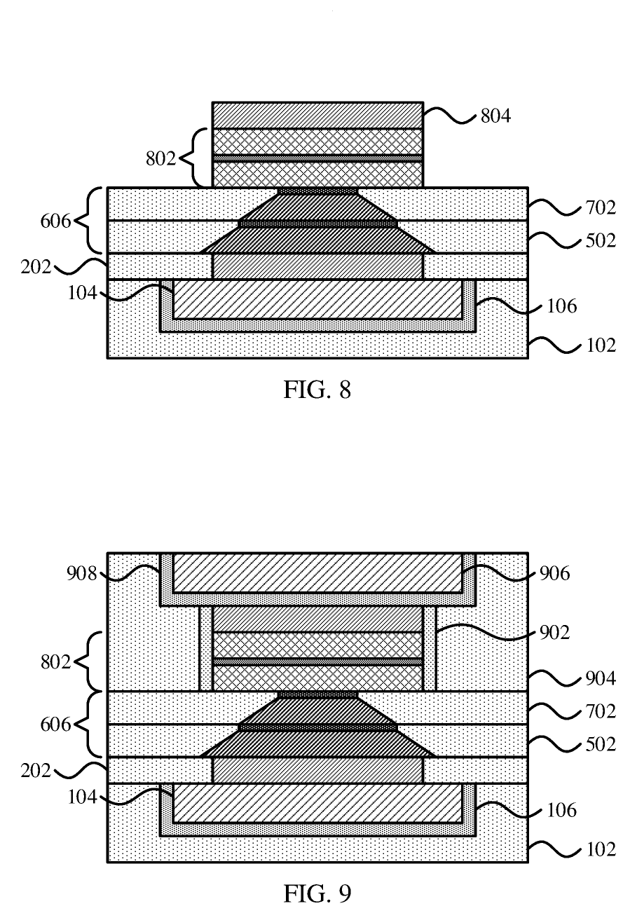

Referring now to FIG. 8, a cross-sectional view of a step in the fabrication of an MTJ device is shown. The top conductor layer 706 and the stack of layers 704 are patterned and anisotropically etched using one or more selective anisotropic etches that stop on the layer of dielectric material 702. This creates MTJ stack 802 and top electrode 804. Because the conductive material of the tiered bottom electrode 606 is protected by the layer of dielectric material 702, none of that material sputters back onto the sidewalls of the MTJ stack 802. Any material from the layer of dielectric material 702 that is kicked back by the etch will be an electrical insulator and will not cause a short-circuit if it happens to redeposit on side surfaces of the MTJ stack 802. The bottom surface of the MTJ stack 802 is larger than a top surface of the tiered bottom electrode.

Referring now to FIG. 9, a cross-sectional view of a step in the fabrication of an MTJ device is shown. Dielectric sidewall spacers 902 are formed on sidewalls of the MTJ stack 802 and the top electrode 804, for example by conformally depositing a dielectric material such as silicon nitride and then selectively and anisotropically etching the dielectric material off of horizontal surfaces. An interlayer dielectric 904, such a silicon dioxide, is deposited around the dielectric sidewall spacers 902 and over the top electrode 804 by any appropriate deposition process. A trench may be formed in the interlayer dielectric 904 using photolithography and a selective anisotropic etch to expose the top electrode 804. A top conductive interconnect 906 is formed in the trench with a diffusion barrier 908.

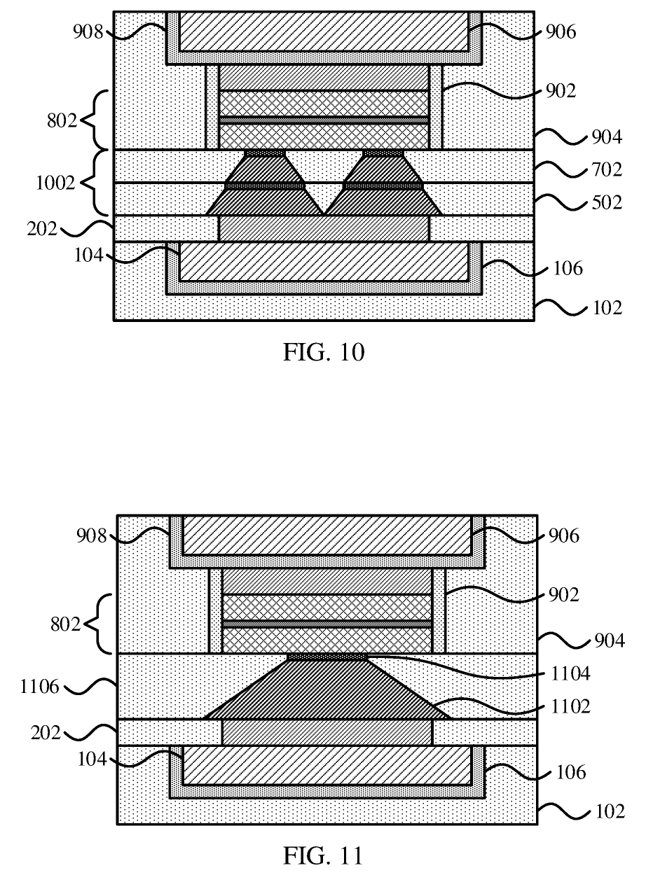

Referring now to FIG. 10, a cross-sectional view of a step in the fabrication of an MTJ device is shown. In some embodiments, instead of a singular tiered bottom electrode 606, multiple tiered bottom electrodes 1002 may be formed. This may be accomplished by, instead of forming a single first conductor platform and a single second conductor platform, forming multiple respective stacks of conductor platforms. As long as the top surface of the multiple second conductor platforms remain covered by the MTJ stack 802, there is no risk of conductive material sputtering back onto the sidewalls of the MTJ stack 802.

For MRAM devices having relatively large lateral dimensions (e.g., having lateral dimensions of 100 nm or greater), multiple tiered bottom electrodes of smaller lateral dimensions may be used to improve the magnetic performance of MRAM devices. This improvement is due to the reduced surface roughness of the bottom electrode.

Referring now to FIG. 11, a cross-sectional view of a step in the fabrication of an MTJ device is shown. In some embodiments, instead of a tiered bottom electrode 606, a unitary bottom electrode 1102 with a single mask 1104 may be formed. The tiered bottom electrode 606 provides more flexibility in the vertical spacing between the MTJ stack 802 and the sloped sidewall surfaces, but a unitary bottom electrode 1102 provides simpler processing and may be suitable if only a small vertical spacing is needed.

The unitary bottom electrode 1102 may be formed by forming a single, thick layer of conductive material (e.g., between about 2nm and about 40nm) and a single mask layer instead of the first conductor layer 302, the first mask layer 304, the second conductor layer 504, and the second mask layer 506. A single interlayer dielectric 1106 may be formed around the unitary bottom electrode 1102 before forming the MTJ stack 802. It should be understood that the embodiments of FIGS. 10 and 11 may be combined to create multiple unitary bottom electrodes.

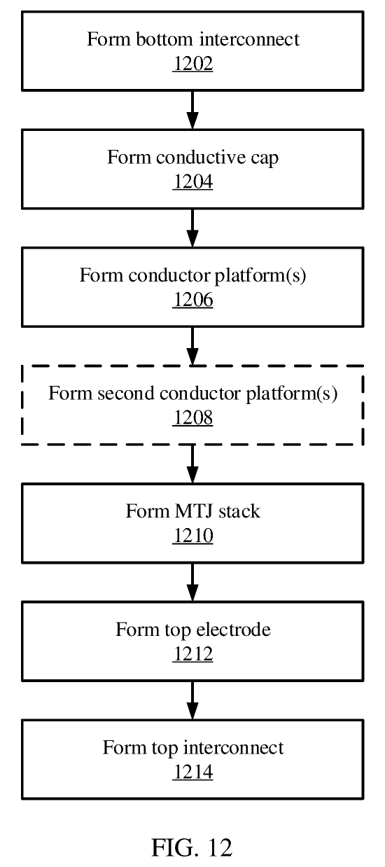

Referring now to FIG. 12, a method of forming an MTJ device is shown. Block 1202 forms bottom conductive interconnect 104, for example by a trench in dielectric layer 102 and filling the trench with conductive material. Block 1204 forms conductive cap 204 on the bottom conductive interconnect 104.

Block 1206 forms the first conductor platform 402 on the conductive cap 204, for example by depositing first conductor layer 302 and first mask layer 304, patterning the first mask 404 from the first mask layer 304, and anisotropically etching the first conductor layer 302. In some embodiments block 1206 may form multiple such first conductive platforms in this fashion. Block 1208 then forms second conductor platform 602 over the first conductor platform 402, for example by depositing second conductor layer 504 and second mask layer 506, patterning the second mask 604 from the second mask layer 506, and anisotropically etching the second conductor layer 504. In some embodiments, block 1208 may form multiple such second conductive platforms over respective first conductor platforms. In some embodiments, the second conductor platform(s) may be omitted, skipping block 1208. In such embodiments, block 1206 creates a unitary bottom electrode 1102.

Block 1210 forms MTJ stack 802, for example by forming a stack of layers 704 and anisotropically etching the same, with the footprint of the MTJ stack 802 being larger than a top surface of the second conductor platform 602. Block 1212 forms top electrode 804 on the MTJ stack 802. In some cases, the MTJ stack 802 and the top electrode 804 may be formed from a single stack of layers with a sequence of selective anisotropic etches. Block 1214 then forms top conductive interconnect 906 over the top electrode 804.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved.

Having described preferred embodiments of tiered bottom electrodes (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A magnetic tunnel junction (MTJ) device, comprising:
a first bottom electrode that includes sloped sidewalls;
an MTJ stack on the first bottom electrode, wherein a bottom surface of the first bottom electrode is larger than a top surface of the first bottom electrode; and
a top electrode on the MTJ stack.

2. The MTJ device of claim 1, wherein the first bottom electrode is a tiered electrode that includes a second conductor platform on a first conductor platform, with a first mask layer between the first conductor platform and the second conductor platform.

3. The MTJ device of claim 2, wherein the first bottom electrode further includes a second mask layer between the second conductor platform and the MTJ stack.

4. The MTJ device of claim 2, wherein the first conductor platform and the second conductor platform are formed from a metal and wherein the first mask layer is formed from a nitride of the metal.

5. The MTJ device of claim 1, further including a second bottom electrode under the MTJ stack.

6. The MTJ device of claim 5, wherein the top surface of the first bottom electrode and a top surface of the second bottom electrode are completely covered by the MTJ stack.

7. The MTJ device of claim 1, wherein a bottom surface of the first bottom electrode is larger than the bottom surface of the MTJ stack.

8. The MTJ device of claim 1, further comprising dielectric spacers on sidewalls of the MTJ stack and the top electrode.

9. The MTJ device of claim 1, further comprising a dielectric layer that fills a space between surfaces of the sloped sidewalls of the first bottom electrode and the bottom surface of the MTJ stack.

10. The MTJ device of claim 1, wherein the sloped sidewalls have a slope between about 30° and about 60°.

11. A magnetic tunnel junction (MTJ) device, comprising:
a first tiered bottom electrode with sloped sidewalls that includes a second conductor platform on a first conductor platform, with a first mask layer between the first conductor platform and the second conductor platform;
an MTJ stack on the first tiered bottom electrode, wherein a bottom surface of the first tiered bottom electrode is larger than a top surface of the first tiered bottom electrode and is smaller than a bottom surface of the first tiered bottom electrode; and
a top electrode on the MTJ stack.

12. The MTJ device of claim 11, wherein the first tiered bottom electrode further includes a second mask layer between the second conductor platform and the MTJ stack.

13. The MTJ device of claim 11, wherein the first conductor platform and the second conductor platform are formed from a metal and wherein the first mask layer is formed from a nitride of the metal.

14. The MTJ device of claim 11, further including a second tiered bottom electrode under the MTJ stack.

15. The MTJ device of claim 14, wherein the top surface of the first tiered bottom electrode and a top surface of the second tiered bottom electrode are completely covered by the MTJ stack.

16. The MTJ device of claim 11, further comprising dielectric spacers on sidewalls of the MTJ stack and the top electrode.

17. The MTJ device of claim 11, further comprising a dielectric layer that fills a space between surfaces of the sloped sidewalls of the first tiered bottom electrode and the bottom surface of the MTJ stack.

18. A method of forming a magnetic tunnel junction (MTJ) device, comprising:
forming a first bottom electrode with sloped sidewalls;
forming a dielectric layer that covers the sloped sidewalls of the first bottom electrode;
forming a set of MTJ layers on the first bottom electrode; and
anisotropically etching the set of MTJ layers to form an MTJ stack, with the first bottom electrode being protected from the etching by the dielectric layer.

19. The method of claim 18, wherein forming the first bottom electrode includes:
forming a first conductive platform with sloped sidewalls; and
forming a second conductive platform with sloped sidewalls on the first conductive platform.

20. The method of claim 19, wherein forming the first conductive platform includes:
forming a first conductive layer;
forming a first mask on the first conductive layer; and
anisotropically etching the first conductive layer around the first mask with an etch that produces the sloped sidewalls.
